(19) United States
(12) Patent Application Publication
(10) Pub. No.: US 2026/0262266 A1
(43) Pub. Date: Sep. 3, 2026

(54) SEMICONDUCTOR DEVICE

(71) Applicant: RENESAS ELECTRONICS CORPORATION, Tokyo (JP)

(72) Inventor: Emi KOBAYASHI, Tokyo (JP)

(21) Appl. No.: 19/409,959

(22) Filed: Dec. 5, 2025

(30) Foreign Application Priority Data
Mar. 3, 2025 (JP) 2025-032775

(51) Int. Cl. H10D 62/10; H10D 30/66; H10D 62/832

(52) U.S. Cl. CPC H10D 62/109; H10D 30/665; H10D 62/107; H10D 62/8325

(57) ABSTRACT

A RESURF region and a source wiring are each formed annularly in a termination region to surround a cell region in a plan view. An impurity region and the outer peripheral wiring are each formed annularly in the termination region to surround the RESURF region and the source wiring in a plan view. The outer peripheral wiring includes a wide portion provided at a corner of the semiconductor device. In a plan view, the width of the wide portion is wider than the width of the outer peripheral wiring other than the wide portion. An opening is provided in a protective film covering the source wiring and the outer peripheral wiring to expose a part of the wide portion. The part of the wide portion exposed in the opening of the protective film constitutes a pad for connecting an external connection terminal.

### CROSS-REFERENCE TO RELATED APPLICATIONS

The disclosure of Japanese Patent Application No. 2025-032775 filed on March 3, 2025, including the specification, drawings and abstract is incorporated herein by reference in its entirety.

### BACKGROUND

The present invention relates to a semiconductor device.

Semiconductor devices equipped with a plurality of semiconductor elements such as power MOSFETs (Metal Oxide Semiconductor Field Effect Transistors) or IGBTs (Insulated Gate Bipolar Transistors) are widely used. Such high withstand voltage semiconductor devices include a cell region where the plurality of semiconductor elements are formed and a termination region surrounding the cell region in a plan view. The termination region is mainly used to improve a breakdown voltage of the semiconductor device.

For example, in Japanese Unexamined Patent Application Publication No. 2018-206842 (Patent Document 1), a source electrode is formed in the cell region, and in the termination region, a gate wiring, a source wiring, and an outer peripheral wiring are formed to surround the source electrode. In a semiconductor substrate of the termination region, a p-type RESURF region, a plurality of p-type field limiting rings and an n-type impurity region are formed. The RESURF region is formed below the source wiring and is electrically connected to the source wiring. The n-type impurity region is formed below the outer peripheral wiring and is electrically connected to the outer peripheral wiring. The plurality of field limiting rings is formed annularly between the source wiring and the outer peripheral wiring in a plan view.

### SUMMARY

A source voltage, such as 0V, is applied to the RESURF region, and a drain voltage, such as 1000V or more, is applied to the n-type impurity region. Therefore, it is necessary to maintain the breakdown voltage of the semiconductor device in the termination region. The plurality of field limiting rings allows the depletion layer to extend in the direction from the plurality of semiconductor elements to the outer peripheral wiring, thereby relaxing the high electric field associated with the high voltage applied to the plurality of semiconductor elements.

During the manufacturing process of the semiconductor device, residues or foreign particles from the metal film may cause a leakage path to form between the gate wiring and the source wiring. In such cases, the power MOSFET may not function as a transistor. Additionally, a leakage path may form between the source wiring and the outer peripheral wiring, making it difficult to relax the electric field in the termination region.

In the case of a leakage path between the gate wiring and the source wiring, test terminals can be connected to a gate pad and a source pad to inspect the electrical characteristics between them, allowing for the determination of the presence of a leakage path.

However, typically, pads are not provided on the outer peripheral wiring. Moreover, a width of the outer peripheral wiring is not designed to be wide enough to connect test terminals. Therefore, in the case of a leakage path between the source wiring and the outer peripheral wiring, the electrical characteristics between them cannot be inspected. Simply widening the outer peripheral wiring would increase the planar size of the semiconductor device, preventing miniaturization. Therefore, if a connection with the test terminals can be made without changing a width of the outer peripheral wiring, the leakage path can be inspected, ensuring the reliability of the semiconductor device.

On the other hand, corners of the semiconductor device are regions where the electric field tends to concentrate. Therefore, in the corners of the semiconductor device, the p-type RESURF region, the plurality of p-type field limiting rings and n-type impurity region are formed with a predetermined radius of curvature to relax the electric field. However, since the electric field still tends to concentrate in the corners compared to other regions, there is a need for technology that can further relax the electric field in the corners, thereby ensuring the reliability of the semiconductor device.

Other problems and novel features will become apparent from the description of this specification and the accompanying drawings.

According to one embodiment, a semiconductor device has a rectangular shape in a plan view. The semiconductor device includes a cell region, a termination region surrounding the cell region in a plan view, a semiconductor substrate with an upper surface and a bottom surface, a RESURF region formed in the semiconductor substrate of the termination region, a first impurity region formed in the semiconductor substrate of the termination region, an interlayer insulating film formed on the upper surface of the semiconductor substrate, a source wiring electrically connected to the RESURF region and formed on the interlayer insulating film of the termination region, a first wiring electrically connected to the first impurity region and formed on the interlayer insulating film of the termination region, and a protective film formed on the interlayer insulating film to cover the source wiring and the first wiring. The RESURF region and the source wiring are each formed annularly in the termination region to surround the cell region in a plan view. The first impurity region and the first wiring are each formed annularly in the termination region to surround the RESURF region and the source wiring in a plan view. The first wiring includes a wide portion provided at the corner of the semiconductor device. In a plan view, a width of the wide portion is wider than a width of the first wiring other than the wide portion. The protective film has a first opening to expose a part of the wide portion. The exposed part of the wide portion at the first opening constitutes a first pad for connecting an external connection terminal.

According to one embodiment, a semiconductor device has a rectangular shape in a plan view. The semiconductor device includes a cell region, a termination region surrounding the cell region in a plan view, a semiconductor substrate with an upper surface and a bottom surface, a RESURF region formed in the semiconductor substrate of the termination region, a first impurity region formed in the semiconductor substrate of the termination region, an interlayer insulating film formed on the upper surface of the semiconductor substrate, a source wiring electrically connected to the RESURF region and formed on the interlayer insulating film of the termination region, and a first wiring electrically connected to the first impurity region and formed on the interlayer insulating film of the termination region. The RESURF region and the source wiring are each formed annularly in the termination region to surround the cell region in a plan view. The first impurity region and the first wiring are each formed annularly in the termination region to surround the RESURF region and the source wiring in a plan view. The first wiring includes a wide portion provided at the corner of the semiconductor device. In a plan view, a width of the wide portion is wider than a width of the first wiring other than the wide portion. The part of the first impurity region located below the wide portion is formed closer to an outer peripheral edge of the wide portion than to an inner peripheral edge of the wide portion in a plan view.

According to one embodiment, it is possible to ensure the breakdown voltage and reliability of the semiconductor device.

### BRIEF DESCRIPTION OF THE DRAWINGS

FIG. 1 is a plan view showing a semiconductor device in the first embodiment.

FIG. 2 is a main portion plan view showing the semiconductor device in the first embodiment.

FIG. 3 is a cross-sectional view showing a part of a termination region in the first embodiment.

FIG. 4 is a cross-sectional view showing a MOSFET in the cell region in the first embodiment.

FIG. 5 is a main portion plan view showing the semiconductor device in the first modified example.

FIG. 6 is a main portion plan view showing the semiconductor device in the second modified example.

FIG. 7 is a cross-sectional view showing a part of the termination region in the second modified example.

FIG. 8 is a main portion plan view showing the semiconductor device in the third modified example.

FIG. 9 is a main portion plan view showing the semiconductor device in an examined example.

FIG. 10 is a cross-sectional view showing a part of the termination region in an examined example.

### DETAILED DESCRIPTION

Hereinafter, embodiments will be described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In this application, the X direction, Y direction, and Z direction described intersect each other and are orthogonal to each other. In this application, the Z direction is a vertical direction, depth direction, or thickness direction of a certain structure. The expressions "plan view" or "in plan" used in this application mean that the plane formed by the X direction and the Y direction is a "plane" and the "plane" is viewed from the Z direction.

Impurities contained in a n-type impurity region is, for example, nitrogen (N), and the impurity contained in the p-type impurity region is, for example, aluminum (Al).

### First Embodiment

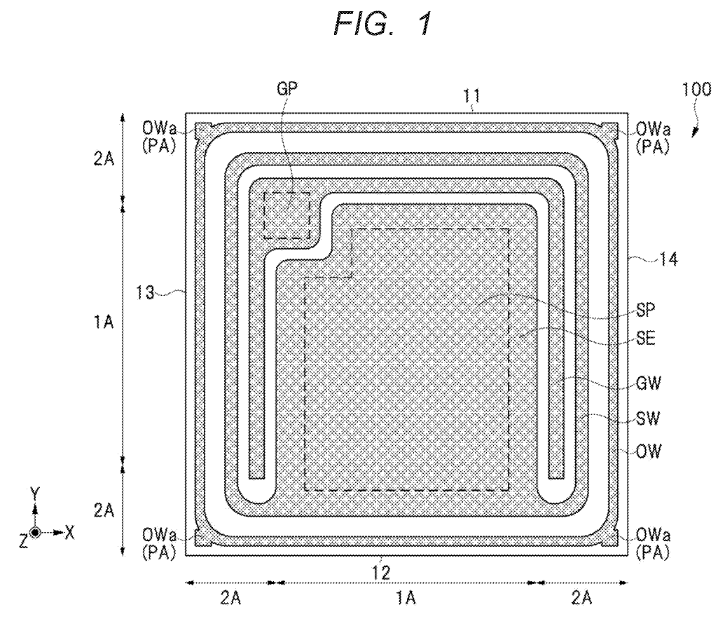

Hereinafter, a semiconductor device 100 in the first embodiment will be described with reference to FIGS. 1 to 4.

As shown in FIG. 1, the semiconductor device 100 has a rectangular shape in plan view. That is, the semiconductor device 100 has sides 11 and 12 along the X direction and sides 13 and 14 along the Y direction, with four corners.

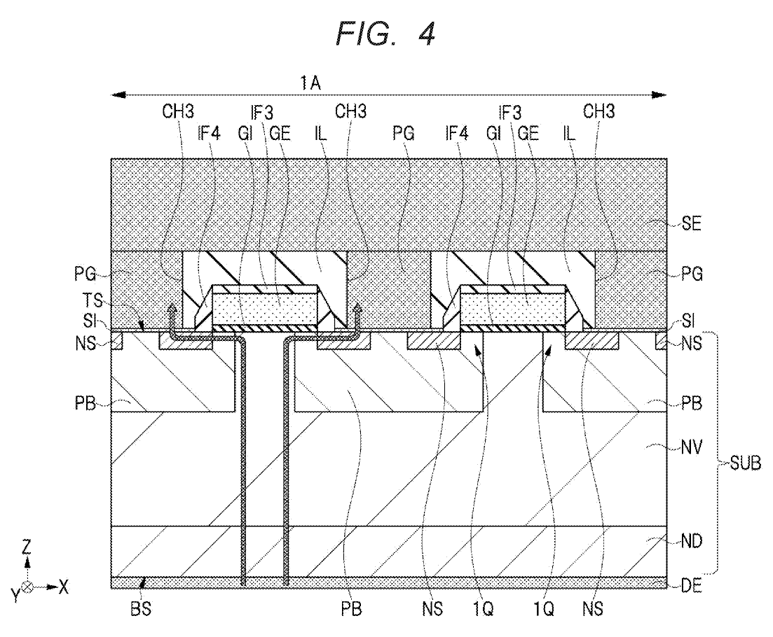

The semiconductor device 100 includes a cell region 1A where a plurality of semiconductor elements are formed, and a termination region 2A surrounding the cell region 1A in plan view. In the first embodiment, an example of the semiconductor element is an n-type MOSFET1Q as shown in FIG. 4.

As shown in FIG. 1, the semiconductor device 100 includes a plurality of wirings. In the cell region 1A, a source electrode SE is formed as wiring. A plurality of MOSFET1Q is formed below the source electrode SE. In the termination region 2A, a gate wiring GW, a source wiring SW, and an outer wiring OW are formed as wirings, respectively. The gate wiring GW, the source wiring SW, and the outer wiring OW each surround the cell region 1A in plan view.

The gate wiring GW surrounds the source electrode SE in plan view. The source wiring SW is integrated with the source electrode SE and is annularly formed to surround the gate wiring GW in plan view. The outer wiring OW is annularly formed to surround the source wiring SW in plan view.

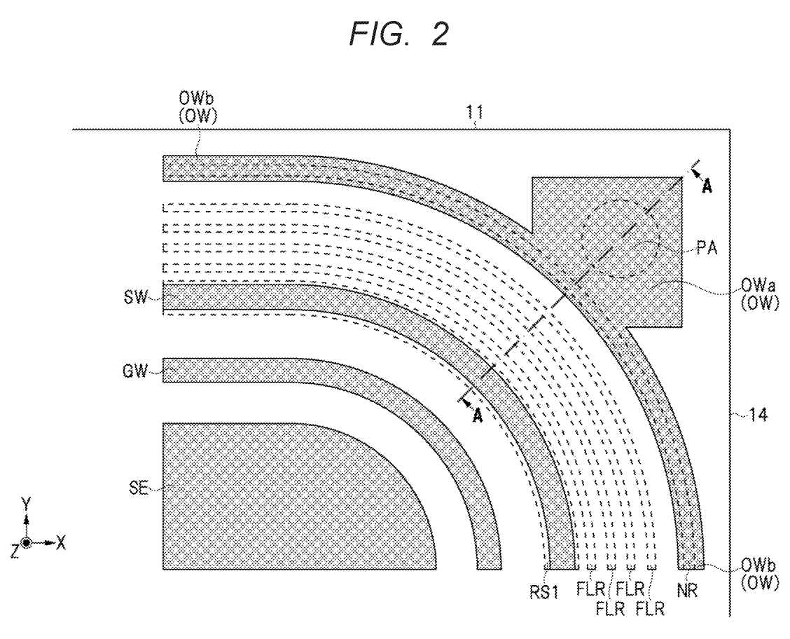

FIG. 2 is an enlarged plan view of one of the four corners of the semiconductor device 100 shown in FIG. 1.

As shown in FIG. 2, the semiconductor device 100 includes a p-type RESURF region RS1, the plurality of p-type field limiting rings FLR and an n-type impurity region NR formed in a semiconductor substrate SUB of the termination region 2A. The RESURF region RS1 is formed below the source wiring SW and is electrically connected to the source wiring SW. The impurity region NR is formed below the outer wiring OW and is electrically connected to the outer wiring OW.

The RESURF region RS1, the plurality of field limiting rings FLR, and the impurity region NR are annularly formed in the termination region 2A to surround the cell region 1A in plan view. The impurity region NR surrounds the RESURF region RS1 and the plurality of field limiting rings FLR in plan view. Each of the plurality of field limiting rings FLR is positioned between the RESURF region RS1 and the impurity region NR in plan view.

As shown in FIGS. 1 and 2, the outer wiring OW, the source wiring SW, the RESURF region RS1, the plurality of field limiting rings FLR, and the impurity region NR each form a planar shape with a predetermined radius of curvature at the corners of the semiconductor device 100. In other words, regions where the outer wiring OW, the source wiring SW, the RESURF region RS1, the plurality of field limiting rings FLR and the impurity region NR are provided, each forming an arc shape in plan view, are the corners of the semiconductor device 100.

The outer wiring OW has four narrow portions OWb extending along at least the four sides 11, 12, 13 and 14, and four wide portions OWa provided at the four corners of the semiconductor device 100. In plan view, a width of the wide portion OWa is wider than a width of the outer wiring OW other than the wide portion OWa (width of the narrow portion OWb). In other words, the wide portion OWa is integrated with the narrow portion OWb and protrudes from the narrow portion OWb in the direction toward the outer wiring OW from the source wiring SW.

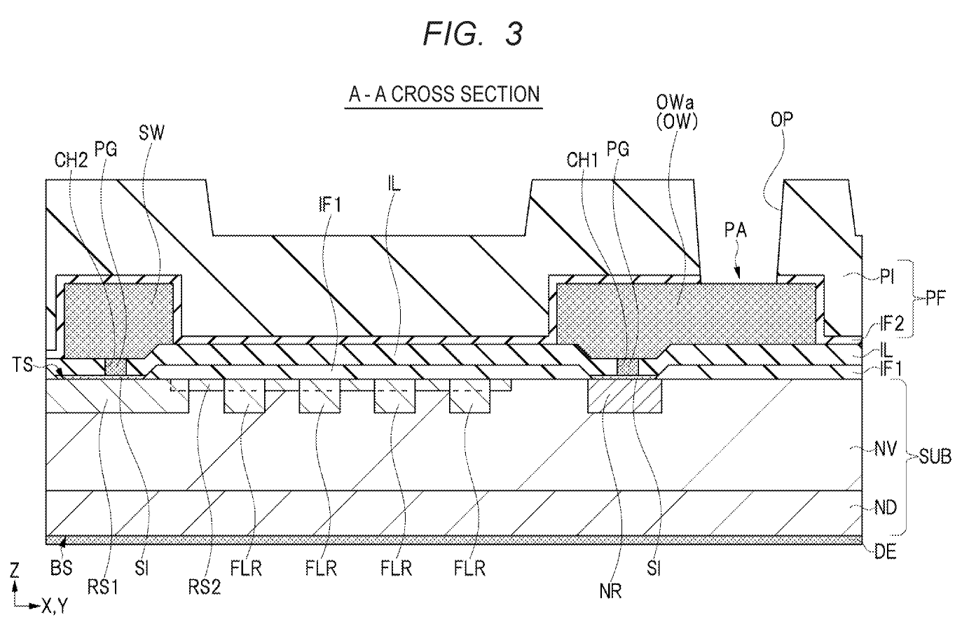

As shown in FIG. 3, the source wiring SW and the outer wiring OW are covered with a protective film PF. The protective film PF is a laminated film including an insulating film IF2 and a resin film PI formed on the insulating film IF2. The insulating film IF2 is, for example, a silicon nitride film. The resin film PI is, for example, a polyimide film. The thickness of the resin film PI is greater than the thickness of the insulating film IF2. The insulating film IF2 is provided to suppress moisture from entering the semiconductor substrate SUB and other components from the outside of the semiconductor device 100.

The protective film PF is provided with an opening OP that opens a part of the wide portion OWa. The portion of the wide portion OWa exposed by the opening OP constitutes a pad PA for connecting an external connection terminal.

Although not shown, the source electrode SE and the gate wiring GW are also covered with the protective film PF. The protective film PF is also provided with openings that open a part of the source electrode SE or a part of the gate wiring GW. As shown by the dashed lines in FIG. 1, the portion of the source electrode SE exposed by the opening constitutes a source pad SP for connecting the external connection terminal, and the portion of the gate wiring GW exposed by the opening constitutes a gate pad GP for connecting the external connection terminal.

By connecting external connection members to the source pad SP and the gate pad GP, the semiconductor device 100 can be electrically connected to other semiconductor devices, lead frames, or wiring substrates. The external connection members are, for example, wires made of aluminum, gold, or copper, or clips made of copper plates.

During testing of the semiconductor device 100, test terminals of a test device may be connected to the pad PA, source pad SP and the gate pad GP as external connection members.

Hereinafter, a cross-sectional structure of the termination region 2A and a cross-sectional structure of the MOSFET1Q formed in the cell region 1A will be described with reference to FIGS. 3 and 4. FIG. 3 is a cross-sectional view along line A-A shown in FIG. 2. FIG. 4 is a cross-sectional view showing a part of the cell region 1A. Note that in FIG. 4, the illustration of the protective film PF shown in FIG. 3 is omitted.

As shown in FIGS. 3 and 4, the semiconductor substrate SUB has an upper surface TS and a bottom surface BS and has n-type conductivity. The semiconductor substrate SUB is made of, for example, silicon (Si), silicon carbide (SiC), gallium nitride (GaN), or diamond. Hereinafter, a case where the semiconductor substrate SUB is made of silicon carbide (SiC) will be exemplified.

The semiconductor substrate SUB has an n-type drift region NV and an n-type drain region ND. The drain region ND is formed in the semiconductor substrate SUB to have a predetermined thickness from the bottom surface BS of the semiconductor substrate SUB toward the upper surface TS of the semiconductor substrate SUB. The impurity concentration of the drain region ND is higher than the impurity concentration of the drift region NV.

The semiconductor substrate SUB may be a laminated body of, for example, an n-type SiC substrate and an n-type SiC layer formed on the n-type SiC substrate by an epitaxial growth method. In that case, an n-type silicon substrate constitutes the drain region ND, and the n-type SiC layer constitutes the drift region NV.

A drain electrode DE is formed under the bottom surface BS of the semiconductor substrate SUB. The drain electrode DE is a single-layer metal film such as an aluminum film, titanium film, nickel film, gold film, or silver film, or a laminated film containing these metal films as appropriate. The drift region NV, the drain region ND, and the drain electrode DE are formed throughout the semiconductor substrate SUB. The drain potential is supplied to the semiconductor substrate SUB (drain region ND, drift region NV) from the drain electrode DE.

### Structure of Termination Region 2A

As shown in FIG. 3, in the semiconductor substrate SUB of the termination region 2A, a p-type RESURF region RS1, a p-type RESURF region RS2, the plurality of p-type field limiting rings FLR and the n-type impurity region NR are formed to reach a predetermined depth from the upper surface TS of the semiconductor substrate SUB. The impurity concentration of the impurity region NR is higher than the impurity concentration of the drift region NV. The RESURF region RS1, the plurality of field limiting rings FLR and the impurity region NR are separated from each other. The RESURF region RS2 is connected to the RESURF region RS1 and the plurality of field limiting rings FLR.

An insulating film IF1 is formed on the upper surface TS of the semiconductor substrate SUB of the termination region 2A. The insulating film IF1 is a silicon oxide film, for example, a TEOS (Tetraethyl Orthosilicate) film. Silicide films SI are formed on the portions of the RESURF region RS1 and the impurity region NR exposed from the insulating film IF1. The silicide film SI is, for example, a nickel silicide film, a cobalt silicide film, or a titanium silicide film.

An interlayer insulating film IL is formed on the upper surface TS of the semiconductor substrate SUB so as to cover the insulating film IF1. The interlayer insulating film IL is a boron and phosphorus-doped silicon oxide (BPSG: Boron Phosphorus Silicon Glass) film.

In the interlayer insulating film IL of the termination region 2A, a hole CH1 reaching the silicide film SI on the impurity region NR and a hole CH2 reaching the silicide film SI on the RESURF region RS1 are formed. Inside each of the holes CH1 and CH2, a plug PG are formed. The plug PG consist of a first barrier metal film and a first conductive film formed on the first barrier metal film. The first barrier metal film is, for example, a titanium nitride film. The first conductive film is, for example, a tungsten film.

On the interlayer insulating film IL of the termination region 2A, the source wiring SW and an outer peripheral wiring OW are formed. The source wiring SW is electrically connected to the RESURF region RS1 via the plug PG and the silicide film SI. The source potential is supplied from the source wiring SW to the RESURF region RS1, the RESURF region RS2 and the plurality of field limiting rings FLR. The outer peripheral wiring OW is electrically connected to the impurity region NR via the plug PG and the silicide film SI. Therefore, the drain potential is supplied from the drain electrode DE to the outer peripheral wiring OW and the impurity region NR.

Although not shown, a hole reaching a gate electrode GE of the MOSFET1Q is also formed in the interlayer insulating film IL of the termination region 2A. Inside the hole, the plug PG is formed. The gate wiring GW is formed on the interlayer insulating film IL of the termination region 2A and is electrically connected to the gate electrode GE via the plug PG. The gate potential is supplied to the gate electrode GE from the gate wiring GW.

The gate wiring GW, the source wiring SW, and the outer peripheral wiring OW consist of, for example, a second barrier metal film and a second conductive film formed on the second barrier metal film. The second barrier metal film is, for example, a titanium-tungsten film. The second conductive film is, for example, an aluminum alloy film with added copper or silicon.

The protective film PF is formed on the interlayer insulating film IL to cover the gate wiring GW, the source wiring SW, and the outer peripheral wiring OW. As described above, the protective film PF of the termination region 2A has an opening OP that exposes a part of the wide portion OWa and an opening that exposes a part of the gate wiring GW.

### Structure of MOSFET1Q in Cell Region 1A

As shown in FIG. 4, the gate electrode GE is formed on the upper surface TS of the semiconductor substrate SUB in the cell region 1A via a gate insulating film GI. An insulating film IF3 is formed on the gate electrode GE. The gate insulating film GI is formed of, for example, a silicon oxide film. The gate electrode GE consists of, for example, a laminated film including a polysilicon film with n-type impurities introduced and a tungsten silicide film formed on the polysilicon film. The insulating film IF3 is formed of, for example, a silicon oxide film.

In the semiconductor substrate SUB of the cell region 1A, a p-type body region PB reaching a predetermined depth from the upper surface TS of the semiconductor substrate SUB is formed. An n-type source region NS is formed in the body region PB. The impurity concentration of the source region NS is higher than the impurity concentration of the drift region NV.

On each side of the gate electrode GE and the insulating film IF3, an insulating film IF4 is formed as a sidewall spacer. The silicide films SI are formed at the exposed portions of the source region NS and the body region PB from the insulating film IF4.

The gate electrode GE is formed to straddle a part of each of the two adjacent body regions PB and the drift region NV located between the two adjacent body regions PB. The portion of the body region PB located below the gate electrode GE via the gate insulating film GI and positioned between the source region NS and the drift region NV in a plan view constitutes the channel region of the MOSFET1Q.

On the upper surface TS of the semiconductor substrate SUB, the interlayer insulating film IL is formed to cover the MOSFET1Q. In the interlayer insulating film IL, a hole CH3 is formed to reach the silicide film SI on the source region NS and the body region PB. Inside the hole CH3, the plug PG is formed. On the interlayer insulating film IL of the cell region 1A, the source electrode SE is formed.

The source electrode SE, like the source wiring SW, consists of the second barrier metal film and the second conductive film formed on the second barrier metal film. The source electrode SE is electrically connected to the source region NS and the body region PB via the plug PG and the silicide film SI. The source potential is supplied to the source region NS and the body region PB from the source electrode SE.

Although not shown, the protective film PF is formed on the interlayer insulating film IL to cover the source electrode SE. As described above, the protective film PF of the cell region 1A has an opening that exposes a part of the source electrode SE.

As indicated by the arrows shown in FIG. 4, the current path of the MOSFET1Q is a path from the drain electrode DE through the drain region ND, the drift region NV, the body region PB (the channel region), the source region NS, the silicide film SI, and the plug PG to the source electrode SE.

### Main Features of the First Embodiment

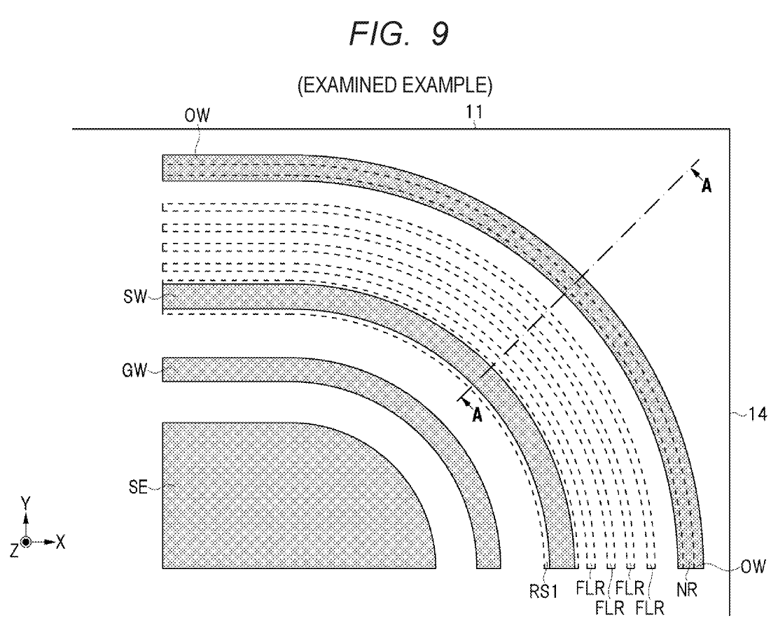

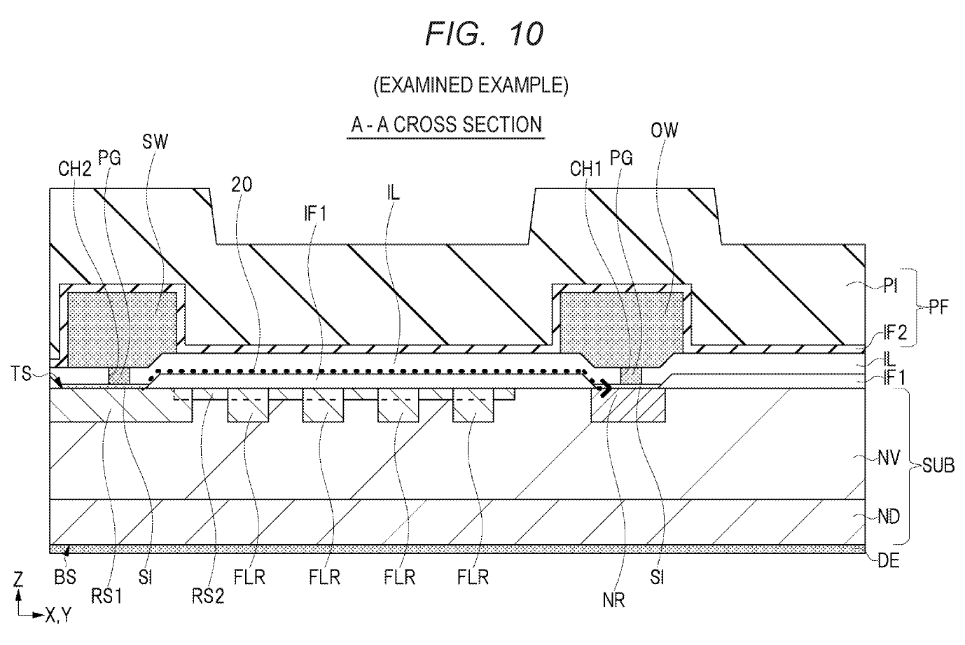

FIGS. 9 and 10 show the semiconductor device of the examined example studied by the inventors of this application. FIG. 10 is a cross-sectional view along line A-A shown in FIG. 9. As shown in FIGS. 9 and 10, in the examined example, the outer peripheral wiring OW does not have the wide portion OWa, and no pad PA is provided. In other words, in the examined example, the entire outer peripheral wiring OW is the narrow portion OWb.

As described above, residues or foreign substances of the metal film generated during the manufacturing process of the semiconductor device may cause a leak path to form between the source wiring SW and the outer peripheral wiring OW. FIG. 10 illustrates a case where an unreacted metal film remains on an insulating film IF1 during the manufacturing process of the silicide film SI, and the leak path 20 is formed due to the unreacted metal film. The leak path 20 is a path from the RESURF region RS1 to the impurity region NR via the insulating film IF1.

The manufacturing process for forming the silicide film SI is performed before the manufacturing process for forming the interlayer insulating film IL. First, a metal film is deposited on the semiconductor substrate SUB to cover the insulating film IF1 and the MOSFET1Q, and heat treatment is applied. As a result, the silicon contained in the exposed portions of the semiconductor substrate SUB from the insulating film IF1 and a insulating film IF4 reacts with the metal film, forming the silicide film SI. For example, the silicide film SI is formed on the upper surfaces of the source region NS, the body region PB, RESURF region RS1 and the impurity region NR. Thereafter, the unreacted metal film is removed. At this time, the unreacted metal film may not be completely removed and may remain as residue. For example, the residue on the insulating film IF1 may cause the leak path 20.

In the case of the leak path between the gate wiring GW and the source wiring SW, test terminals can be connected to the gate pad GP and the source pad SP, respectively, and the electrical characteristics between them can be inspected to determine the presence or absence of the leak path. Therefore, after inspection, measures can be taken to completely remove the unreacted metal film, providing the highly reliable semiconductor device 100 with suppressed occurrence of the leak path.

However, normally, no pad is provided on the outer peripheral wiring OW. Therefore, it is not possible to determine the presence or absence of the leak path 20 between the source wiring SW and the outer peripheral wiring OW. A method of designing the width of the outer peripheral wiring OW (width of the narrow portion OWb) to be wide enough to connect test terminals can be considered, but simply widening the width of the outer peripheral wiring OW increases the planar size of the semiconductor device 100, making it impossible to miniaturize the semiconductor device 100.

To secure a connection point with the test terminal without changing the planar size of the semiconductor device 100, if the width of the outer peripheral wiring OW is designed to be wider towards the inside of the semiconductor device 100, a distance between the outer peripheral wiring OW and the field limiting ring FLR becomes closer, and the outer peripheral wiring OW affects the electric field distribution around the field limiting ring FLR.

Also, if the width of the outer peripheral wiring OW is designed to be wider towards the outside of the semiconductor device 100, the outer peripheral wiring OW becomes closer to the outer edge of the semiconductor device 100, making it easier for moisture to penetrate inside the semiconductor device 100. Therefore, these methods are not preferable as they may reduce the reliability of the semiconductor device 100.

In the first embodiment, the outer peripheral wiring OW includes the wide portion OWa provided at the corner of the semiconductor device 100. The portion of the wide portion OWa exposed by the opening OP constitutes the pad PA. Therefore, by connecting test terminals to the source pad SP and the pad PA, respectively, and measuring the electrical characteristics between them, the presence or absence of the leak path 20 can be determined. Thereafter, measures can be taken to completely remove the unreacted metal film, providing the highly reliable semiconductor device 100 with suppressed occurrence of the leak path 20.

Thus, according to the first embodiment, it is possible to connect with the test terminal without changing the width of the outer peripheral wiring OW, inspect the leak path 20, and ensure the reliability of the semiconductor device 100.

In the first embodiment, the case where the wide portion OWa and the pad PA are provided at all four corners of the semiconductor device 100 is illustrated. However, since the outer peripheral wiring OW is formed annularly along the outer edge of the semiconductor device 100, from the viewpoint of connecting test terminals to the source pad SP and the pad PA, the wide portion OWa and the pad PA only need to be provided at one of the four corners of the semiconductor device 100.

### First Modified Example

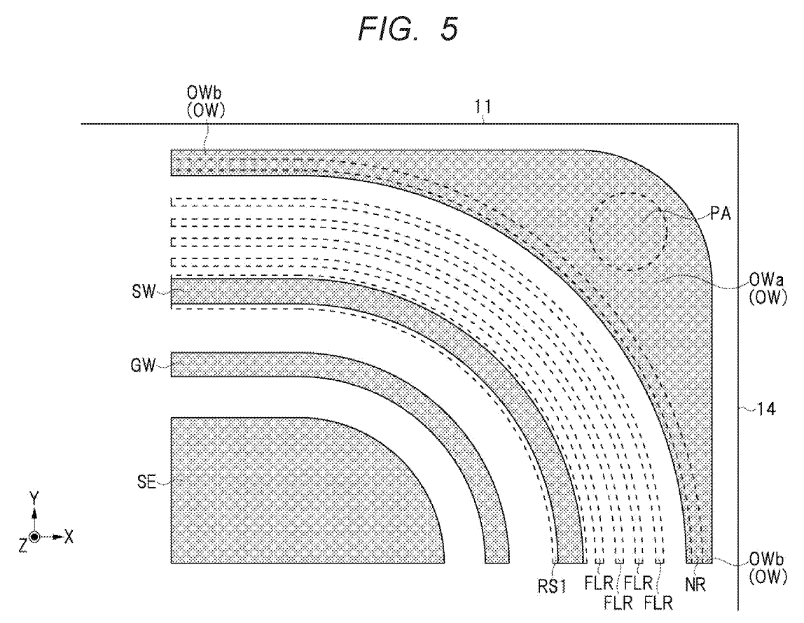

The semiconductor device in the first modified example of the first embodiment will be described below with reference to FIG. 5. In the following description, differences from the first embodiment will be mainly described, and the description of overlapping points with the first embodiment will be omitted.

In the first embodiment, the wide portion OWa had a shape with corners in plan view, but in the first modified example, the wide portion OWa has a shape without such corners.

As shown in FIG. 5, in the first modified example, similar to the first embodiment, the width of the wide portion OWa in plan view is wider than the width of the outer peripheral wiring OW other than the wide portion OWa (width of the narrow portion OWb). In the first modified example, the width of the wide portion OWa becomes wider as it moves away from the narrow portion OWb. In other words, not only the inner peripheral edge of the outer peripheral wiring OW but also an outer peripheral edge of the outer peripheral wiring OW form a planar shape with a predetermined radius of curvature, and the radius of curvature of the inner peripheral edge of the outer peripheral wiring OW is larger than the radius of curvature of the outer peripheral edge of the outer peripheral wiring OW.

During the post-process, when the semiconductor device 100 is packaged using an encapsulating resin such as resin, stress is applied to the wide portion OWa from the encapsulating resin. If there are corners in the wide portion OWa, stress tends to concentrate at the corners, which may cause issues such as disconnection of the wide portion OWa. By shaping the planar shape of the wide portion OWa as in the first modified example, such issues can be more easily suppressed, and the reliability of the semiconductor device 100 can be more easily ensured.

### Second Modified Example

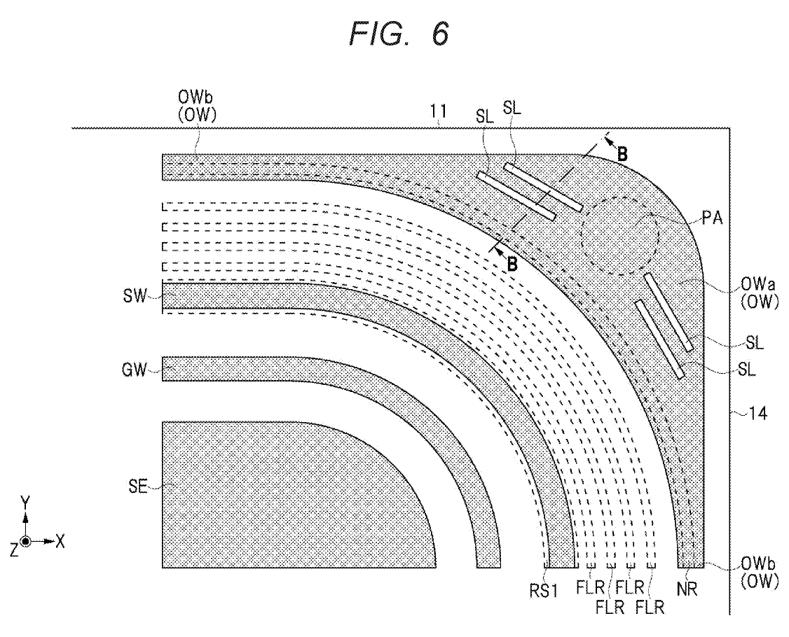

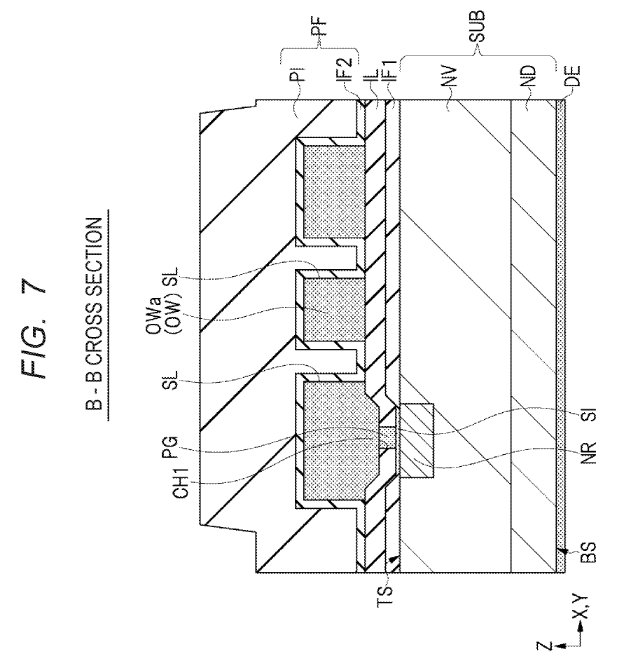

The semiconductor device in the second modified example of the first modified example will be described below with reference to FIGS. 6 and 7. In the following description, differences from the first modified example will be mainly described, and the description of overlapping points with the first modified example will be omitted. FIG. 7 is a cross-sectional view along line B-B shown in FIG. 6.

As shown in FIGS. 6 and 7, in the second modified example, a slit SL penetrating the wide portion OWa is provided in part of the wide portion OWa of the first modified example. The slit SL extends in a direction intersecting the direction from the source wiring SW to the outer peripheral wiring OW in plan view and forms a closed shape. The inside of the slit SL is filled with the insulating film IF2 and a resin film PI. At least one slit SL is provided in the wide portion OWa or a plurality of slits SL may be provided.

The wide portion OWa includes an aluminum alloy film as a conductive film. In cases where the planar area of the wide portion OWa is relatively large, as in the second modified example, aluminum slide tends to occur due to expansion stress when the semiconductor device 100 is used after being shipped as a product.

Note that aluminum slide is one of the failure mechanisms of semiconductor devices. The uppermost layer wiring, such as the outer peripheral wiring OW (wide portion OWa) formed on the semiconductor substrate SUB, is subjected to expansion stress due to thermal cycles occurring during product use. As a result, issues such as deformation or disconnection of the uppermost layer wiring occur.

Therefore, in the second modified example, the slit SL is provided in part of the wide portion OWa. The resin film PI embedded inside the slit SL functions as a stopper for expansion stress. Consequently, issues such as deformation or disconnection of the wide portion OWa are less likely to occur, and the reliability of the semiconductor device 100 can be more easily ensured.

The closed shape of the slit SL may be, for example, a stripe shape, a dotted shape, a lattice shape, a mesh shape, a staggered shape, a honeycomb shape, a wavy line shape or an arc shape, or a combination of these shapes.

Also, in the direction from the source wiring SW to the outer peripheral wiring OW, a minimum width of the outer peripheral wiring OW (width of the narrow portion OWb) is, for example, 20micrometers, and a maximum width of wide portion OWa is, for example, 270micrometers. Therefore, the width of the slit SL can be set to, for example, 3 micrometers or more and 135micrometers or less.

### Third Modified Example

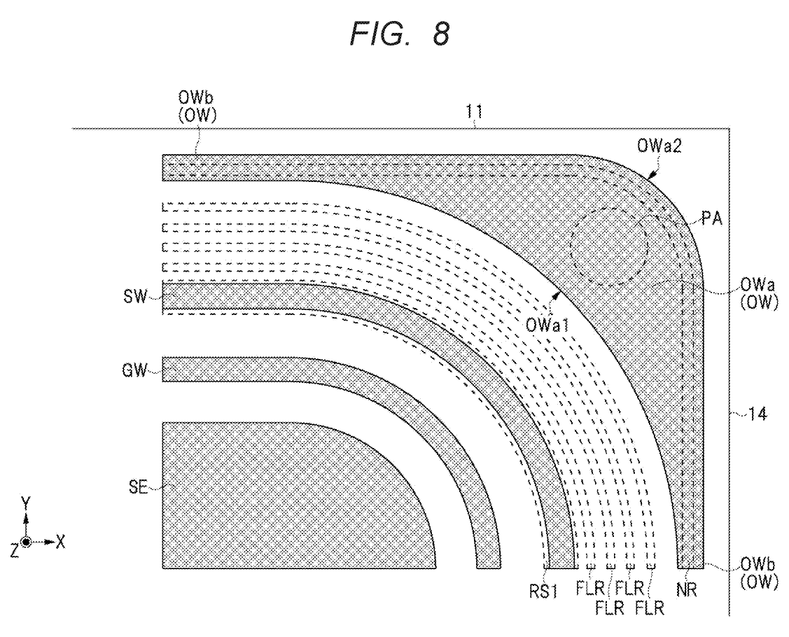

The semiconductor device in the third modified example of the first modified example will be described below with reference to FIG. 8. In the following description, differences from the first modified example will be mainly described, and the description of overlapping points with the first modified example will be omitted.

As described above, even if the p-type RESURF region RS1, the plurality of p-type field limiting rings FLR and the n-type impurity region NR each form a planar shape with a predetermined radius of curvature, the corners of the semiconductor device 100 are regions where the electric field tends to concentrate compared to other regions. The third modified example relates to the aspect of relaxing the electric field at the corners of the semiconductor device 100.

As shown in FIG. 8, the wide portion OWa has an inner peripheral edge OWa1 and an outer peripheral edge OWa2 that is farther from the RESURF region RS1 than the inner peripheral edge OWa1. The portion of the impurity region NR located below the wide portion OWa is formed closer to the outer peripheral edge OWa2 than the inner peripheral edge OWa1 in plan view. In other words, the impurity region NR also has an inner peripheral edge and an outer peripheral edge farther from the RESURF region RS1 than the inner peripheral edge, and below the wide portion OWa, the inner peripheral edge of the impurity region NR is closer to the outer peripheral edge OWa2 than the inner peripheral edge OWa1 in plan view.

Therefore, a distance between the impurity region NR and the RESURF region RS1 is longest between the portion of the impurity region NR located below the wide portion OWa and the RESURF region RS1. That is, a creepage distance between the impurity region NR and the RESURF region RS1 can be made longer than, for example, in the examined example (see FIGS. 9 and 10).

For example, in the examined example of FIGS. 9 and 10, a distance between the source wiring SW and the outer peripheral wiring OW is almost constant in the corner and non-corner regions of the semiconductor device 100. To electrically connect the outer peripheral wiring OW and the impurity region NR, it is necessary to place the impurity region NR below the outer peripheral wiring OW. Therefore, the impurity region NR cannot be moved away from the RESURF region RS1 alone.

In the third modified example, since the wide portion OWa is provided in the outer peripheral wiring OW, the impurity region NR can be provided along the outer peripheral edge OWa2, and the impurity region NR can be moved away from the RESURF region RS1. Therefore, further relaxation of the electric field can be achieved at the corners of the semiconductor device 100, and the reliability of the semiconductor device 100 can be ensured.

Moreover, it is preferable that the relaxation of the electric field is performed at all four corners of the semiconductor device 100. Therefore, in the third modified example, the outer peripheral wiring OW has four wide portions OWa provided at the four corners of the semiconductor device 100, and the portions of the impurity region NR located below the four wide portions OWa are each formed closer to the outer peripheral edge OWa2 than the inner peripheral edge OWa1 in plan view.

Note that the slit SL of the second modified example may be provided in the wide portion OWa of the third modified example.

Although the present invention has been described in detail based on the embodiments, the present invention is not limited to these embodiments and can be variously modified without departing from the gist thereof.

For example, the semiconductor element formed in the cell region 1A is not limited to a MOSFET and may be an IGBT or a Schottky barrier diode.

What is claimed is:

1. A semiconductor device having a rectangular shape in plan view, comprising:
a cell region in which a plurality of semiconductor elements is formed;
a termination region surrounding the cell region in plan view;
a semiconductor substrate having an upper surface and a bottom surface;
a RESURF region formed in the semiconductor substrate of the termination region such that the RESURF region reaches a predetermined depth from the upper surface of the semiconductor substrate;
a first impurity region formed in the semiconductor substrate of the termination region such that the first impurity region reaches a predetermined depth from the upper surface of the semiconductor substrate;
an interlayer insulating film formed on the upper surface of the semiconductor substrate;
a source wiring electrically connected to the RESURF region and formed on the interlayer insulating film of the termination region;
a first wiring electrically connected to the first impurity region and formed on the interlayer insulating film of the termination region; and
a protective film formed on the interlayer insulating film such that the protective film covers the source wiring and the first wiring, wherein
the RESURF region and the source wiring are each formed annularly in the termination region such that the RESURF region and the source wiring surround the cell region in plan view,
the first impurity region and the first wiring are each formed annularly in the termination region such that the first impurity region and the first wiring surround the RESURF region and the source wiring in plan view,
the first wiring includes a wide portion provided at a corner of the semiconductor device,
a width of the wide portion is wider than a width of the first wiring other than the wide portion, in plan view,
the protective film is provided with a first opening such that the protective film expose a part of the wide portion, and
the part of the wide portion exposed by the first opening configures a first pad for connecting an external connection terminal.

2. The semiconductor device according to claim 1, further comprising:
a first insulating film formed on the upper surface of the semiconductor substrate and formed between the RESURF region and the first impurity region, in plan view; and
silicide films respectively formed at portions of the RESURF region and the first impurity region exposed from the first insulating film, wherein
the interlayer insulating film is formed such that the interlayer insulating film covers the first insulating film.

3. The semiconductor device according to claim 1, further comprising:
a slit penetrating the wide portion is provided in a part of the wide portion, wherein
the slit extends in a direction intersecting a direction from the source wiring to the first wiring in plan view and has a closed shape.

4. The semiconductor device according to claim 3, wherein
a width of the slit is 3 micrometers or more and 135 micrometers or less.

5. The semiconductor device according to claim 3, wherein
the closed shape is a stripe shape, a dotted shape, a lattice shape, a mesh shape, a staggered shape, a honeycomb shape, a wavy line shape or an arc shape, or a combination thereof.

6. The semiconductor device according to claim 1, further comprising:
a plurality of second impurity regions formed in the semiconductor substrate, wherein
the semiconductor substrate is of a first conductivity type,
the plurality of second impurity regions is of a second conductivity type opposite to the first conductivity type,
the plurality of second impurity regions is each located between the RESURF region and the first impurity region in plan view and formed annularly.

7. The semiconductor device according to claim 6, wherein
the RESURF region is of the second conductivity type, and the first impurity region is of the first conductivity type.

8. The semiconductor device according to claim 1, wherein
the wide portion and the first pad are provided only at one of four corners of the semiconductor device.

9. The semiconductor device according to claim 1, wherein
the protective film includes a silicon nitride film and a polyimide film formed on the silicon nitride film.

10. A semiconductor device having a rectangular shape in plan view, comprising:
a cell region in which a plurality of semiconductor elements is formed;
a termination region surrounding the cell region in plan view;
a semiconductor substrate having an upper surface and a bottom surface;
a RESURF region formed in the semiconductor substrate of the termination region such that the RESURF region reaches a predetermined depth from the upper surface of the semiconductor substrate;
a first impurity region formed in the semiconductor substrate of the termination region such that the first impurity region reaches a predetermined depth from the upper surface of the semiconductor substrate;
an interlayer insulating film formed on the upper surface of the semiconductor substrate;
a source wiring electrically connected to the RESURF region and formed on the interlayer insulating film of the termination region;
a first wiring electrically connected to the first impurity region and formed on the interlayer insulating film of the termination region, wherein
the RESURF region and the source wiring are each formed annularly in the termination region such that the RESURF region and the source wiring surround the cell region in plan view,
the first impurity region and the first wiring are each formed annularly in the termination region such that the first impurity region and the first wiring surround the RESURF region and the source wiring in plan view,
the first wiring includes a wide portion provided at a corner of the semiconductor device,
a width of the wide portion is wider than a width of the first wiring other than the wide portion in plan view, and
a portion of the first impurity region located below the wide portion is formed closer to an outer peripheral edge of the wide portion than to an inner peripheral edge in plan view.

11. The semiconductor device according to claim 10, wherein
a distance between the first impurity region and the RESURF region is longest between a portion of the first impurity region located below the wide portion and the RESURF region.

12. The semiconductor device according to claim 10, further comprising:
a first insulating film formed on the upper surface of the semiconductor substrate and formed between the RESURF region and the first impurity region, in plan view; and
silicide films respectively formed at portions of the RESURF region and the first impurity region exposed from the first insulating film, wherein
the interlayer insulating film is formed such that the interlayer insulating film covers the first insulating film.

13. The semiconductor device according to claim 10, further comprising:
a slit penetrating the wide portion is provided in a part of the wide portion, wherein
the slit extends in a direction intersecting a direction from the source wiring to the first wiring in plan view and has a closed shape.

14. The semiconductor device according to claim 13, wherein
a width of the slit is 3 micrometers or more and 135 micrometers or less.

15. The semiconductor device according to claim 13, wherein
the closed shape is a stripe shape, a dotted shape, a lattice shape, a mesh shape, a staggered shape, a honeycomb shape, a wavy line shape or an arc shape, or a combination thereof.

16. The semiconductor device according to claim 10, further comprising:
a plurality of second impurity regions formed in the semiconductor substrate, wherein
the semiconductor substrate is of a first conductivity type,
the plurality of second impurity regions is of a second conductivity type opposite to the first conductivity type,
the plurality of second impurity regions is each located between the RESURF region and the first impurity region in plan view and formed annularly.

17. The semiconductor device according to claim 16, wherein
the RESURF region is of the second conductivity type, and the first impurity region is of the first conductivity type.

18. The semiconductor device according to claim 10, wherein
the first wiring has four wide portions provided at four corners of the semiconductor device, and
the portions of the first impurity region located below the four wide portions are each formed closer to the outer peripheral edge of the wide portion than to an inner peripheral edge in plan view.

19. The semiconductor device according to claim 10, further comprising:
a protective film formed on the interlayer insulating film such that the protective film covers the source wiring and the first wiring, wherein
the protective film is provided with a first opening to expose a part of the wide portion, and
the part of the wide portion exposed by the first opening configures a first pad for connecting an external connection terminal.

20. The semiconductor device according to claim 19, wherein
the protective film includes a silicon nitride film and a polyimide film formed on the silicon nitride film.
